(19) United States
(12) Patent Application Publication
(10) Pub. No.: US 2013/0120082 A1
(43) Pub. Date: May 16, 2013

(54) TWO-PORT RESONATORS ELECTRICALLY COUPLED IN PARALLEL

(71) Applicants: Chengjie Zuo, San Diego, CA (US); Changhan Yun, San Diego, CA (US); Chi Shun Lo, San Diego, CA (US); Sanghoon Joo, San Diego, CA (US); Jonghae Kim, San Diego, CA (US)

(72) Inventors: Chengjie Zuo, San Diego, CA (US); Changhan Yun, San Diego, CA (US); Chi Shun Lo, San Diego, CA (US); Sanghoon Joo, San Diego, CA (US); Jonghae Kim, San Diego, CA (US)

(73) Assignee: QUALCOMM Incorporated, San Diego, CA (US)

(21) Appl. No.: 13/293,522

(22) Filed: Nov. 10, 2011

(51) Int. Cl. H03H 9/58; H01L 41/22

(52) U.S. Cl. 333/189; 29/25.35

(57) ABSTRACT

Systems and method for wideband filter designs comprising two-port piezoelectric resonators electrically coupled in parallel. A resonating circuit comprises a first piezoelectric resonator formed of a first configuration, and a second piezoelectric resonator formed of a second configuration such that outputs of the first and second piezoelectric resonators have a 180-degree phase difference for a same input. The first piezoelectric resonator and the second piezoelectric resonator are coupled electrically in parallel. The first and second piezoelectric resonators have different resonating frequencies respectively controlled by lateral dimensions of the piezoelectric resonators.

### FIELD OF DISCLOSURE

Disclosed embodiments are directed to wideband filters using resonators. More particularly, exemplary embodiments are directed to wideband filter designs comprising two-port piezoelectric resonators electrically coupled in parallel.

### BACKGROUND

Piezoelectric resonators are known in the art for converting mechanical energy into electrical energy, or vice versa. Mechanical energy may be manifested in the form of vibrations in a piezoelectric material, such as AlN, ZnO, PZT, etc. The vibrations may be translated to electrical signals of desired frequency. Piezoelectric resonators find various applications. For example, the resonators may be used for generating clock pulses in integrated circuits. Piezoelectric resonators may also be configured for use in filters for selectively filtering signals of desired frequency.

Wideband filters are commonly used to selectively allow a desired range/band of frequencies to pass through the filter, while rejecting all other frequencies. Accordingly, the frequency response of a wide band signal is characterized by a high/on state over the range/band of allowable frequencies and a low/off state over the remaining frequencies. It is desirable that the frequency response is a smooth straight line over the band of allowable frequencies such that the filter may efficiently pass this band of allowable frequencies with uniform amplification and minimum distortion.

With respect to the frequency response of a single piezoelectric resonator, a sharp peak occurs at the particular resonating frequency of the resonator. With reference to FIG. 1, the frequency response of a single piezoelectric resonator is illustrated. As shown, the frequency response dies down over frequencies neighboring the resonating frequency of 900 MHz. Therefore, in general, a single piezoelectric resonator in isolation may only be ideally suited to pass the corresponding resonating frequency.

In order to assess the quality of wideband filter designs, certain parameters are commonly used in the art. Coefficient of electromechanical coupling (kₜ²)is a parameter used to represent a numerical measure of efficiency of energy conversion between mechanical and electrical energy in piezoelectric resonators. Another parameter, quality factor (Q) is used to characterize a resonator's bandwidth with respect to its resonant frequency. In general a higher Q indicates a lower rate of energy loss. In other words, high Q resonators display high amplitudes around the resonant frequency and more stability.

Conventional designs for wideband filters may include bulk acoustic wave (BAW) resonators. BAW filters may be formed by coupling two or more piezoelectric BAW resonators of differing resonating frequencies, such that a flat and wide pass band may be formed by utilizing a large value of coefficient of electromechanical coupling (kₜ²) over a few resonating modes, such as film bulk acoustic wave resonators (FBAR) resonating modes. A Ladder filter topology as known in the art is commonly used for such conventional designs of BAW filters. In these topologies, the characteristic of large kₜ² limits the design of wideband filters to a small number of resonating modes, thus limiting the range of operating frequency. In order to realize multiple operating frequencies on a single chip, piezoelectric contour-mode resonators have been explored, but these designs are limited to characteristics of small kₜ². However, there are no known designs for BAW resonators or filter topologies for wideband filters which exhibit small kₜ² for a particular resonator technology.

Further, resonators are also characterized based on the direction of oscillations induced with respect to the direction of electrical pulses generated. With reference now to FIG. 2, a “d31” resonating mode of a conventional piezoelectric resonator, piezoelectric resonator 200 is illustrated. The d31 resonating mode refers to a mode of excitation of piezoelectric resonator 200, wherein an electrical signal applied in the vertical (Z) direction results in resonating oscillations of piezoelectric resonator 200, used for signal generation in the lateral (X) direction. The resonating frequency in d31 mode is governed by dimension “W” of piezoelectric resonator 200, in the lateral direction. Correspondingly, a transverse piezoelectric coefficient or d31 coefficient is a measure of frequency response characteristics related to lateral dimension W of the resonator.

A second mode of resonation, also illustrated with regard to piezoelectric resonator 200 in FIG. 2 is the “d33” resonating mode. The d33 resonating mode refers to a mode of excitation, wherein an electrical signal applied in the vertical (Z) direction results in resonating oscillations in the same direction, i.e. vertical (Z) direction. Accordingly, resonating frequency in d33 mode is governed by vertical dimension “T” of piezoelectric resonator 200. Correspondingly, a d33 coefficient is a measure of frequency response characteristics related to vertical dimension T of the resonator.

With respect to prior art single piezoelectric resonators utilizing materials such as AlN in d31 mode, the transverse piezoelectric coefficient d31 is poor, and usually in the order of one-third the value of the corresponding d33 coefficient. Accordingly, piezoelectric resonators with transverse vibrations using AlN, exhibit a poor coefficient of electromechanical coupling kₜ². Therefore d31 mode resonators are not ideally suited for wideband filter applications, in spite of features such as high quality factor Q, which leads to low motional resistance and low filter insertion loss. However, d33 mode resonators are also not ideal, because d33 mode resonators are limited to having a single operating frequency per fabrication or per wafer.

With respect to prior art single piezoelectric resonators utilizing materials such as ZnO and PZT in d31 mode, as opposed to AlN as described above, improved transverse piezoelectric coefficient d31 and coefficient of electromechanical coupling kₜ²are observed. Therefore, materials such as ZnO and PZT may be better suited for wideband filter applications. However, resonators formed from ZnO and PZT display low quality factor Q, and correspondingly, high motional resistance and high filter insertion loss.

Another known resonator design involves piezoelectric-on-substrate configurations. Piezoelectric materials such as AlN, ZnO, and PZT are formed on non-piezoelectric substrates such as Si and Diamond. In piezoelectric-on-substrate configurations, the body of the piezoelectric resonator is predominantly the non-piezoelectric substrate. Therefore, the effective coefficient of electromechanical coupling kₜ², is very low, and accordingly, unfavorable for wideband filter applications.

Yet another known resonator design includes film bulk acoustic wave resonators (FBAR), formed from materials such as AlN, ZnO, and PZT, for example, as disclosed in P. D. Bradley, et al., IUS 2002, which is incorporated by reference herein. Drawbacks of film bulk acoustic wave resonators include: the resonant frequency is determined by the thickness of the piezoelectric film, which results in a single filter resonant frequency per wafer (per chip). As discussed previously, wideband filters for different bands need multiple wafers/fabrications with different piezoelectric layer thicknesses. Accordingly, FBARs cannot be suitably employed in devices which require multi-band/multi-mode filters on a single chip.

Accordingly, there is a need in the art for wideband filter designs using piezoelectric resonators which overcome the aforementioned drawbacks. In other words, there is a need in the art for wideband filters with piezoelectric resonators on a single chip, which are configurable over multiple operating frequencies, display low kₜ², and have a smooth and well defined pass band.

### SUMMARY

Exemplary embodiments of the invention are directed to systems and methods for wideband filter designs comprising two-port piezoelectric resonators electrically coupled in parallel.

For example, an exemplary embodiment is directed to a resonating circuit comprising: a first piezoelectric resonator formed of a first configuration; and a second piezoelectric resonator formed of a second configuration such that the second piezoelectric resonator is coupled to the first piezoelectric resonator and outputs of the first and second piezoelectric resonators have a 180-degree phase difference for a same input.

Another exemplary embodiment is directed to a method of forming a resonating circuit comprising: forming a first piezoelectric resonator of a first configuration; forming a second piezoelectric resonator of a second configuration, wherein outputs of the first and second piezoelectric resonators have a 180-degree phase difference for a same input; and coupling the first piezoelectric resonator to the second piezoelectric resonator.

Yet another exemplary embodiment is directed to a method of forming a resonating circuit comprising: step for forming a first piezoelectric resonator of a first configuration; step for forming a second piezoelectric resonator of a second configuration, wherein outputs of the first and second piezoelectric resonators have a 180-degree phase difference for a same input; and step for coupling the first piezoelectric resonator to the second piezoelectric resonator.

Another exemplary embodiment is directed to a system comprising: a first resonating means formed of a first configuration; and a second resonating means formed of a second configuration such that the second resonating means is coupled to the first resonating means and outputs of the first and second resonating means have a 180-degree phase difference for a same input.

### BRIEF DESCRIPTION OF THE DRAWINGS

The accompanying drawings are presented to aid in the description of embodiments of the invention and are provided solely for illustration of the embodiments and not limitation thereof

FIG. 1 illustrates the frequency response of a single piezoelectric resonator.

FIG. 2 illustrates d31 and d33 resonating modes in a conventional piezoelectric one-port resonator.

FIG. 3 illustrates multi-finger resonator 300 according to an exemplary embodiment.

FIG. 4 illustrates resonating circuit 400 comprising two or more multi-finger two-port resonators of alternating first and second configurations coupled in parallel.

FIG. 5A illustrates an effective frequency response of resonating circuit 400 of FIG. 4.

FIG. 5B illustrates a frequency response of a resonating circuit with inductor matching to flatten the pass band.

FIG. 6 illustrates resonating circuit 600 comprising two or more multi-finger resonators of alternating first and second configurations coupled in parallel and additional circuit elements such as inductors.

FIG. 7 illustrates resonating circuit 700 comprising two or more cascaded resonating circuits.

FIG. 8 is a flowchart illustration of a method for forming a resonating circuit according to exemplary embodiments.

FIG. 9 illustrates an exemplary wireless communication system 900 in which an embodiment of the disclosure may be advantageously employed.

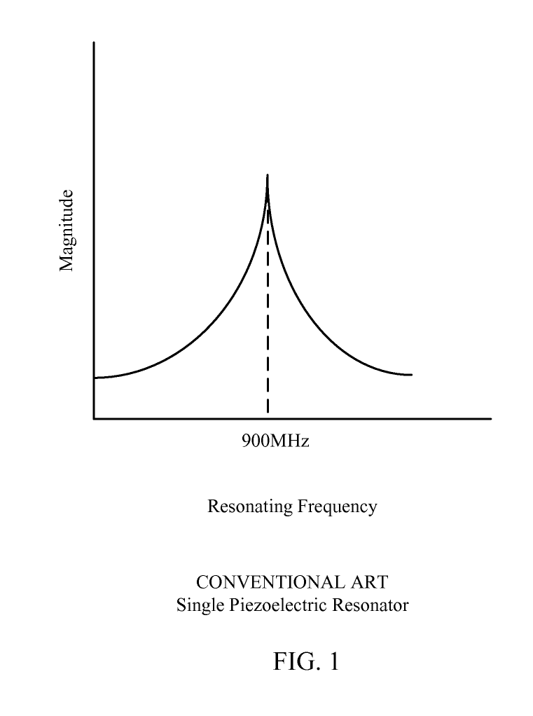

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Exemplary embodiments avoid the aforementioned problems associated with prior art piezoelectric resonators. Exemplary configurations may include wideband filters using piezoelectric resonators with lateral resonations, with characteristics of high Q, relatively low kₜ², and a smooth and well defined pass band frequency response.

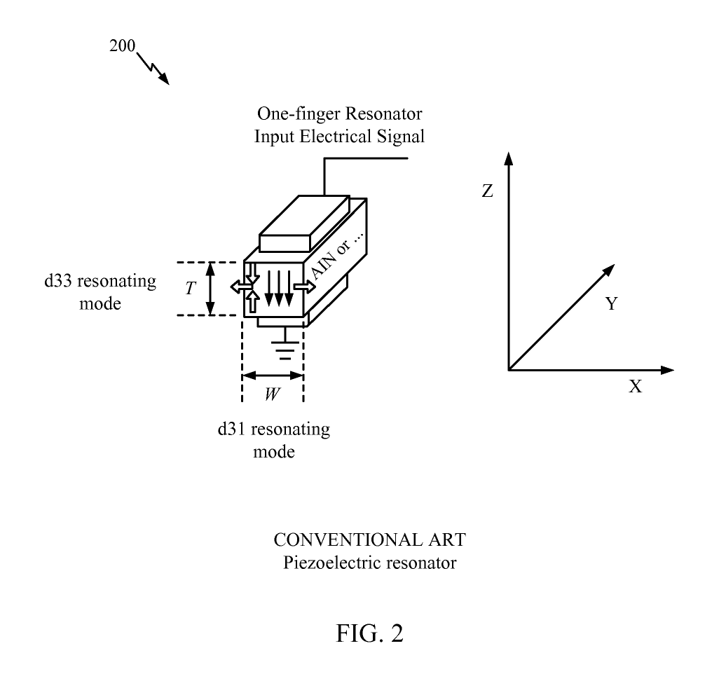

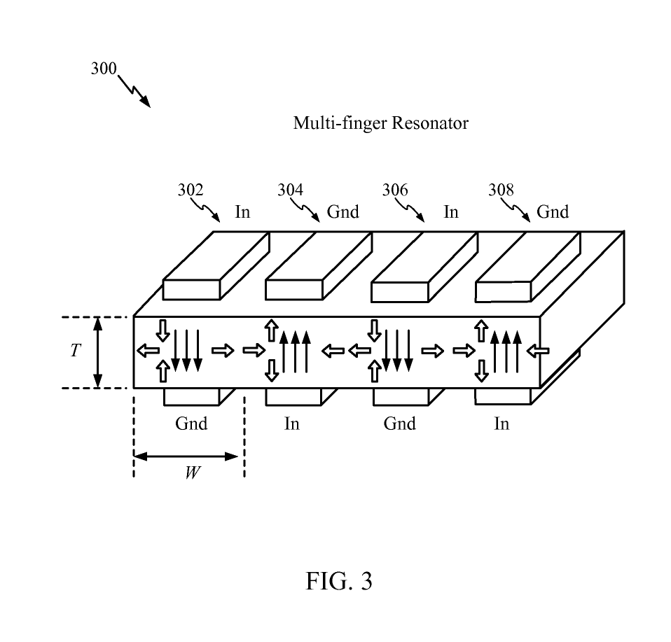

With reference now to FIG. 3, one-port multi-finger resonator 300 is illustrated. As previously described with reference to FIG. 2, the lateral dimension W of piezoelectric resonator 200 governs the resonating frequency. Multi-finger resonator 300 may comprise two or more fingers or individual piezoelectric resonating elements such as 302, 304, 306, and 308. By integrating the piezoelectric resonating elements 302-308 in a single structure, the width of multi-finger resonator 300, and correspondingly, the resonating frequency may be adjusted. As shown, multi-finger resonator 300 may be configured with alternating ports on the top and bottom portion coupled to input and ground for piezoelectric resonating elements 302-308. The input “in” terminals and the ground “gnd” terminals combine to form an electrical port, thus making multi-finger resonator 300 a one-port device. In other embodiments, by configuring selected terminals as input ports, and selected other electrodes as output ports, a two-port resonator may be constructed. As described with regard to the configurations of input and output ports below, phase of multi-finger resonators may be suitably adjusted.

Two or more multi-finger two-port resonators with different port configurations may be coupled in parallel for use in wideband filter applications. Configurations may include circuit topologies wherein output ports are out of phase (i.e. a 180 degree phase difference) with each other, while input ports are coupled together to a same terminal. Embodiments may include resonating circuits comprising multi-finger two-port resonators with alternate port configurations, in order to provide a smoother effective wideband frequency response. Moreover, addition of circuit elements such as inductors to provide inductor matching may smoothen the pass band of the frequency response of wideband filter topologies.

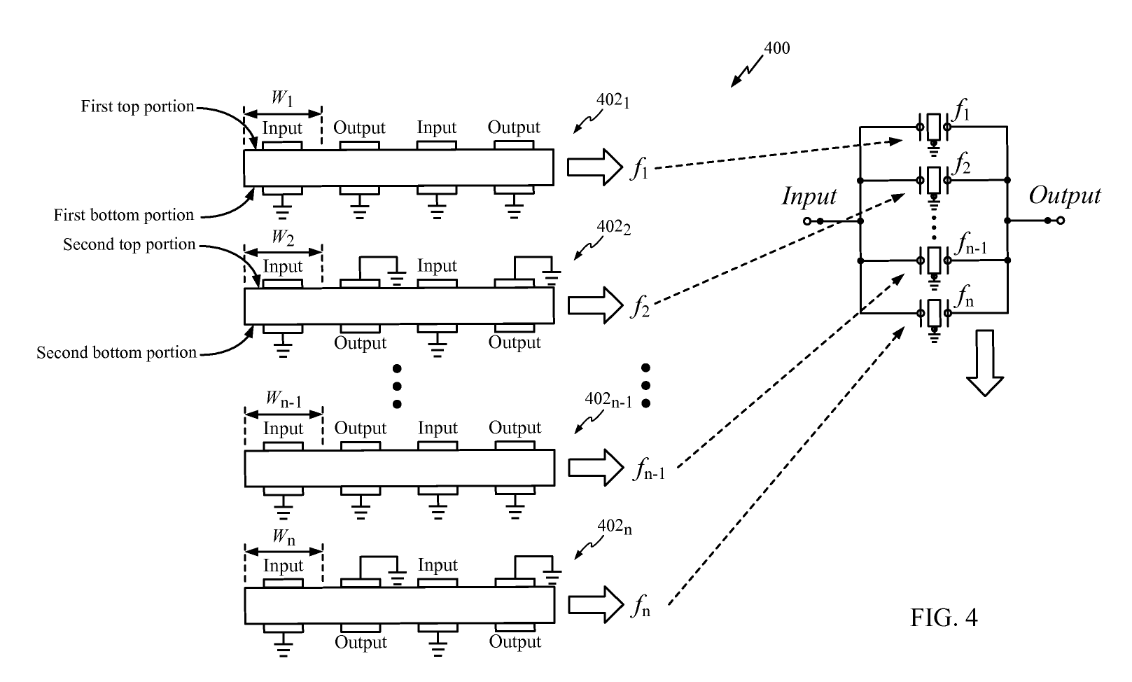

With reference now to FIG. 4, resonating circuit 400 with piezoelectric resonating elements in two configurations will be described. The ports of the two configurations are adjusted such that outputs of the two configurations have a 180-degree phase difference at a same input. The piezoelectric resonating elements may be formed from piezoelectric materials such as AlN, ZnO, PZT and Lithium niobate (LiNbO₃). The piezoelectric resonating elements may be excited by combining both d31 and d33 resonating modes, such that effective electromechanical coupling kₜ² of resonating circuit 400 may be maximized.

With continuing reference to FIG. 4, resonating circuit 400 comprises n two-port multi-finger resonators 402₁-402ₙ coupled in parallel. Each of the n multi-finger resonators 402₁-402ₙ may be formed of one of at least two two-port configurations, a first configuration and a second configuration. The first and second configuration may be selected such that the outputs of the first and second configuration have a 180-degree phase difference for a same input. In the illustrated embodiment, the first configuration comprises alternating input and output ports on the top portion (first top portion) of a multi-finger resonator and further comprising the bottom portion (first bottom portion) of the multi-finger resonator coupled to ground. As shown in FIG. 4, odd-numbered multi-finger resonator 402₁ belongs to the first configuration, and has a resonating frequency f₁.

Correspondingly, the second configuration may comprise input ports on the top portion (second top portion) and output ports on the bottom portion (second bottom portion). Ground connections for the input and output ports may be derived from the opposite side of the input and output ports respectively. As shown in FIG. 4, even-numbered multi-finger resonator 402₂ belongs to the second configuration, and has a resonating frequency f₂. One of ordinary skill will recognize that f1 and f2 will have a phase difference of 180-degrees.

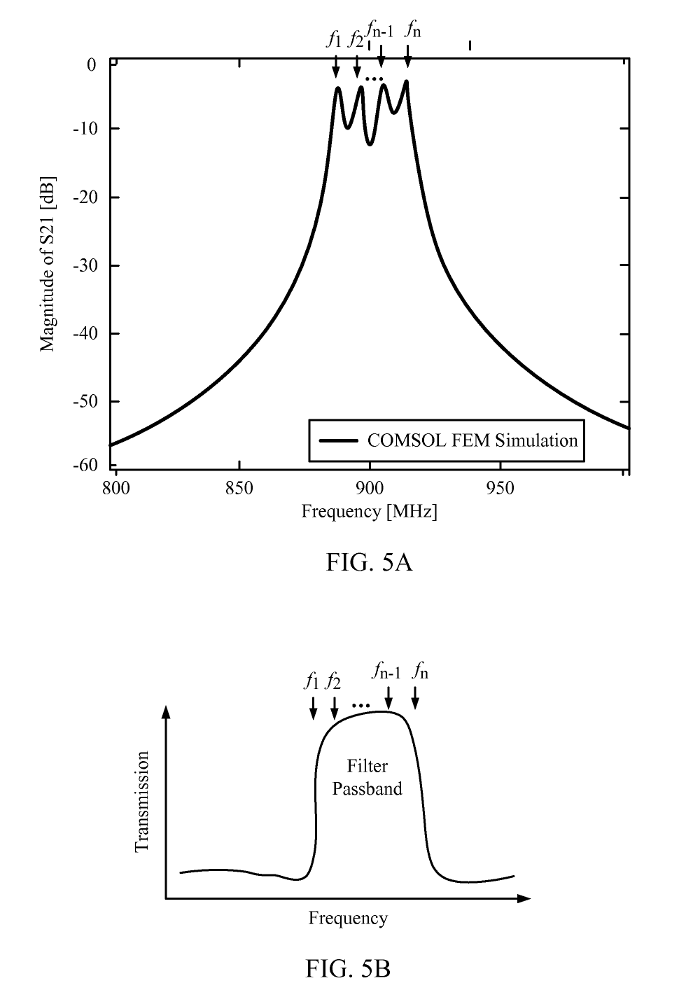

With reference again to FIG. 4, the n multi-finger resonators 402₁-402ₙ may be arranged in parallel with alternating first and second configurations, such that peaks and valleys may be normalized in the effective frequency response of resonating circuit 400. The respective resonating frequencies of multi-finger resonators 402₁-402ₙ may be altered by controlling respective widths W₁-Wₙ, of the n multi-finger resonators. Accordingly, resonating circuit 400 configured in the manner described above with respect to FIG. 4 may generate a wideband filter with frequency response as shown in FIG. 5A. As shown in FIG. 5A, the frequency response comprises a pass band spanning the range of frequencies f₁-fₙ. While resonating circuit 400 may have improved frequency response characteristics, the frequency response may still include small peaks and valleys.

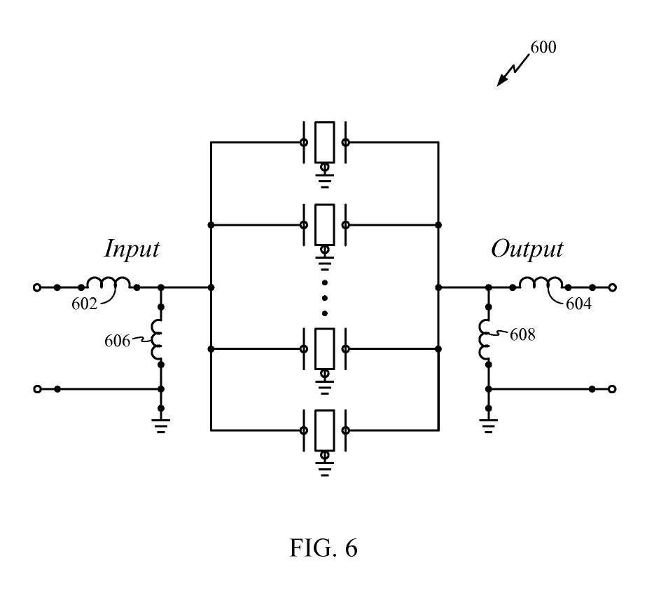

Accordingly, exemplary embodiments may comprise additional circuit elements to generate a smooth frequency response. With reference to FIG. 6, resonating circuit 600 comprises additional circuit elements such as inductors 602, 604, 606, and 608. Resonating circuit 600 may generate the smooth pass band frequency response illustrated in FIG. 5B. Capacitors may also be included appropriately to influence the frequency response.

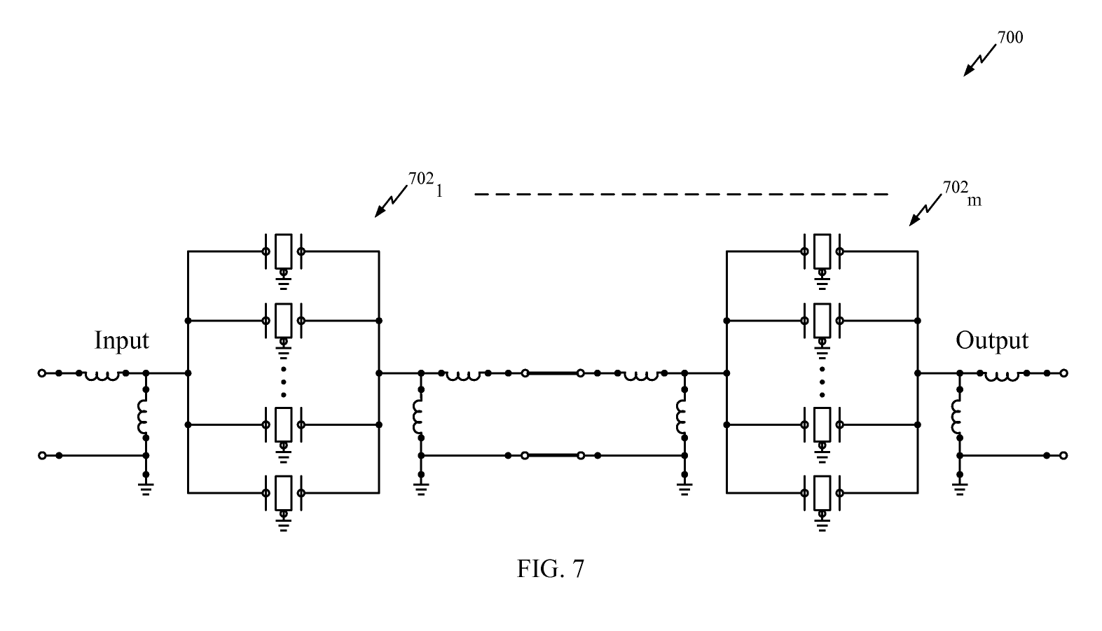

With reference now to FIG. 7, yet another exemplary embodiment is illustrated, wherein m resonating circuits 702₁-702ₘ formed from resonating circuits such as resonating circuit 400 or resonating circuit 600, may be cascaded to form wideband filters with smooth frequency response characteristics.

Accordingly exemplary embodiments may comprise arrangements of multi-finger resonators in parallel. Additionally, embodiments may include arrangements wherein multi-finger resonators may be formed from one of at least two two-port configurations. Such exemplary embodiments may avoid problems associated with prior art piezoelectric resonators and may be used for wideband filter applications with smooth and well defined frequency response characteristics. While exemplary embodiments may provide smooth wideband filter responses with low kₜ² two-port resonators, some embodiments may also exhibit improved performance with high kₜ² and high Q.

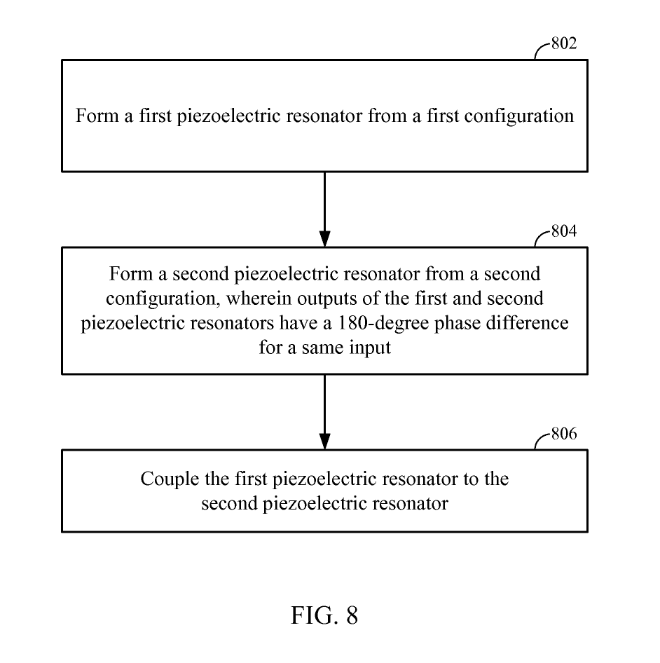

It will be appreciated that embodiments include various methods for performing the processes, functions and/or algorithms disclosed herein. For example, as illustrated in FIG. 8, an embodiment can include a method for forming a resonator comprising: forming a first piezoelectric resonator from a first configuration (e.g. multi-finger two-port resonator 402₁ of FIG. 4 in the first configuration, wherein a first bottom portion is coupled to ground and a first top portion is coupled to alternating input and output ports)—Block 802; forming a second piezoelectric resonator from a second configuration, wherein outputs of the first and second piezoelectric resonators have a 180-degree phase difference for a same input (e.g. multi-finger two-port resonator 402₂ of FIG. 4 in the second configuration, wherein a second bottom portion is coupled alternatively to ground and output ports, a second top portion is coupled alternatively to input ports and ground)—Block 804; and coupling the first piezoelectric resonator to the second piezoelectric resonator—Block 806.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for forming a resonator. Accordingly, the invention is not limited to illustrated examples and any means for performing the functionality described herein are included in embodiments of the invention.

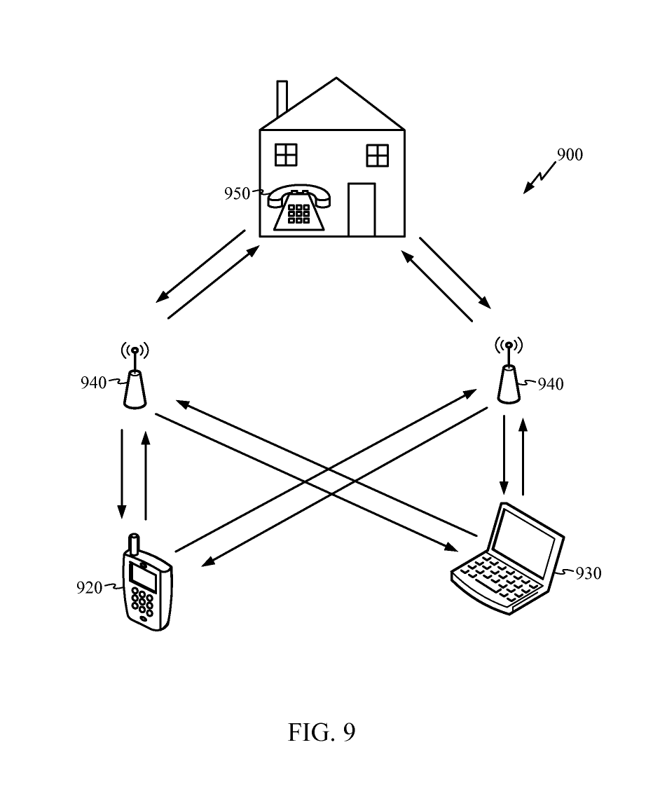

FIG. 9 illustrates an exemplary wireless communication system 900 in which an embodiment of the disclosure may be advantageously employed. For purposes of illustration, FIG. 9 shows three remote units 920, 930, and 950 and two base stations 940. In FIG. 9, remote unit 920 is shown as a mobile telephone, remote unit 930 is shown as a portable computer, and remote unit 950 is shown as a fixed location remote unit in a wireless local loop system. For example, the remote units may be mobile phones, hand-held personal communication systems (PCS) units, portable data units such as personal data assistants, GPS enabled devices, navigation devices, settop boxes, music players, video players, entertainment units, fixed location data units such as meter reading equipment, or any other device that stores or retrieves data or computer instructions, or any combination thereof. Although FIG. 9 illustrates remote units according to the teachings of the disclosure, the disclosure is not limited to these exemplary illustrated units. Embodiments of the disclosure may be suitably employed in any device which includes active integrated circuitry including memory and on-chip circuitry for test and characterization.

The foregoing disclosed devices and methods are typically designed and are configured into GDSII and GERBER computer files, stored on a computer readable media. These files are in turn provided to fabrication handlers who fabricate devices based on these files. The resulting products are semiconductor wafers that are then cut into semiconductor die and packaged into a semiconductor chip. The chips are then employed in devices described above.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A resonating circuit comprising:
a first piezoelectric resonator formed of a first configuration; and
a second piezoelectric resonator formed of a second configuration such that the second piezoelectric resonator is coupled to the first piezoelectric resonator and outputs of the first and second piezoelectric resonators have a 180-degree phase difference for a same input.

2. The resonating circuit of claim 1, wherein the first configuration comprises a first bottom portion coupled to ground and a first top portion coupled to alternating input and output ports; and
the second configuration comprises a second top portion coupled to alternating input ports and ground, and a second bottom portion coupled to alternating output ports and ground.

3. The resonating circuit of claim 1, wherein the coupling comprises coupling the first piezoelectric resonator and the second piezoelectric resonator electrically in parallel.

4. The resonating circuit of claim 1, wherein resonating frequencies of the first and second piezoelectric resonators are controlled by their respective lateral dimensions.

5. The resonating circuit of claim 1, further comprising one or more piezoelectric resonators of the first configuration and one or more piezoelectric resonators of the second configuration, coupled in parallel with the first piezoelectric resonator and the second piezoelectric resonator, in alternating arrangements of the first configuration and the second configuration.

6. The resonating circuit of claim 1 cascaded with one or more separate resonating circuits.

7. The resonating circuit of claim 1, further comprising inductors and/or capacitors.

8. The resonating circuit of claim 1, wherein the first and second piezoelectric resonators are formed from one of AlN, ZnO, Lithium niobate (LiNbO₃), and PZT.

9. The resonating circuit of claim 1, integrated in a wideband filter.

10. The resonating circuit of claim 1, integrated in at least one semiconductor die.

11. The resonating circuit of claim 1, integrated into a device, selected from the group consisting of a set top box, music player, video player, entertainment unit, navigation device, communications device, personal digital assistant (PDA), fixed location data unit, and a computer.

12. A method of forming a resonating circuit comprising:
forming a first piezoelectric resonator of a first configuration;
forming a second piezoelectric resonator of a second configuration, wherein outputs of the first and second piezoelectric resonators have a 180-degree phase difference for a same input; and
coupling the first piezoelectric resonator to the second piezoelectric resonator.

13. The method claim 12, wherein the first configuration comprises a first bottom portion coupled to ground and a first top portion coupled to alternating input and output ports; and
the second configuration comprises a second top portion coupled to alternating input ports and ground, and a second bottom portion coupled to alternating output ports and ground.

14. The method of claim 12, wherein coupling the first piezoelectric resonator and the second piezoelectric resonator comprises coupling the first piezoelectric resonator and the second piezoelectric resonator electrically in parallel.

15. The method of claim 12, comprising controlling a resonating frequency of the first piezoelectric resonator by a first lateral dimension of the first piezoelectric resonator, and controlling the resonating frequency of the second piezoelectric resonator by a second lateral dimension of the second piezoelectric resonator.

16. The method of claim 12, further comprising coupling one or more piezoelectric resonators of the first configuration and one or more piezoelectric resonators of the second configuration, in parallel with the first piezoelectric resonator and the second piezoelectric resonator, in alternating arrangements of the first configuration and the second configuration.

17. The method of claim 12 further comprising cascading the resonating circuit with one or more separate resonating circuits.

18. The method of claim 12, further comprising electrically coupling inductors and/or capacitors to the resonating circuit.

19. The method of claim 12, comprising forming the piezoelectric resonators from one of AlN, ZnO, Lithium niobate (LiNbO₃), and PZT.

20. The method of claim 12, further comprising integrating the resonating circuit in a wideband filter.

21. A system comprising:
a first resonating means formed of a first configuration; and
a second resonating means formed of a second configuration such that the second resonating means is coupled to the first resonating means and outputs of the first and second resonating means have a 180-degree phase difference for a same input.

22. The system of claim 21 wherein the first configuration comprises a first bottom portion coupled to ground and a first top portion coupled to alternating input and output ports; and the second configuration comprises a second top portion coupled to alternating input ports and ground, and a second bottom portion coupled to alternating output ports and ground.

23. The system of claim 21, wherein resonating frequencies of the first and second resonating means are controlled by respective lateral dimensions of the first and second resonating means.

24. The system of claim 21, further comprising one or more first resonating means and one or more second resonating means, coupled in parallel in alternating arrangements of the first configuration and the second configuration.

25. The system of claim 21 cascaded with one or more resonating circuits.

26. The system of claim 21, integrated in a wideband filter.

27. The system of claim 21, integrated in at least one semiconductor die.

28. The system of claim 21, integrated into a device, selected from the group consisting of a set top box, music player, video player, entertainment unit, navigation device, communications device, personal digital assistant (PDA), fixed location data unit, and a computer.

29. A method of forming a resonating circuit comprising:
step for forming a first piezoelectric resonator of a first configuration;
step for forming a second piezoelectric resonator of a second configuration, wherein outputs of the first and second piezoelectric resonators have a 180-degree phase difference for a same input; and
step for coupling the first piezoelectric resonator to the second piezoelectric resonator.

30. The method claim 29, wherein the first configuration comprises a first bottom portion coupled to ground and a first top portion coupled to alternating input and output ports; and
the second configuration comprises a second top portion coupled to alternating input ports and ground, and a second bottom portion coupled to alternating output ports and ground.

31. The method of claim 29, wherein step for coupling the first piezoelectric resonator and the second piezoelectric resonator comprises step for coupling the first piezoelectric resonator and the second piezoelectric resonator electrically in parallel.

32. The method of claim 29, comprising step for controlling a resonating frequency of the first piezoelectric resonator by a first lateral dimension of the first piezoelectric resonator, and controlling the resonating frequency of the second piezoelectric resonator by a second lateral dimension of the second piezoelectric resonator.

33. The method of claim 29, further comprising step for coupling one or more piezoelectric resonators of the first configuration and one or more piezoelectric resonators of the second configuration, in parallel with the first piezoelectric resonator and the second piezoelectric resonator, in alternating arrangements of the first configuration and the second configuration.

34. The method of claim 29 further comprising step for cascading the resonating circuit with one or more separate resonating circuits.

35. The method of claim 29, further comprising step for integrating the resonating circuit in a wideband filter.
